(19) United States
(12) Patent Application Publication
(10) Pub. No.: US 2025/0167155 A1
(43) Pub. Date: May 22, 2025

(54) SEMICONDUCTOR PACKAGES

(71) Applicant: SAMSUNG ELECTRONICS CO., LTD., Suwon-si (KR)

(72) Inventors: SEUNGSOO HA, Suwon-si (KR); Seunggeol RYU, Suwon-si (KR); YUN-HEE LEE, Suwon-si (KR); Yiseul HAN, Suwon-si (KR)

(73) Assignee: SAMSUNG ELECTRONICS CO., LTD., Suwon-si (KR)

(21) Appl. No.: 18/785,840

(22) Filed: Jul. 26, 2024

(30) Foreign Application Priority Data
Nov. 20, 2023 (KR) 10-2023-0161506

(51) Int. Cl. H01L 23/00; H01L 23/31; H01L 23/49; H01L 23/498; H01L 25/10; H10B 80/00

(52) U.S. Cl. CPC H01L 24/20; H01L 23/49822; H01L 24/24; H01L 25/105; H01L 23/3107; H01L 23/49; H01L 23/49816; H01L 24/16; H01L 24/32; H01L 24/73; H01L 2224/16227; H01L 2224/214; H01L 2224/24146; H01L 2224/32225; H01L 2224/73204; H01L 2224/73259; H01L 2225/1041; H10B 80/00

(57) ABSTRACT

A semiconductor package may include a lower redistribution layer, a first semiconductor chip on the lower redistribution layer, a second semiconductor chip on the first semiconductor chip, under-bump patterns between the first semiconductor chip and the second semiconductor chip, and connection terminals between the under-bump patterns and the second semiconductor chip. The under-bump patterns may include a first under-bump pattern connected to two of the connection terminals and a second under-bump pattern connected to one of the connection terminals. A power or ground voltage of the second semiconductor chip may be applied through the first under-bump pattern.

### CROSS-REFERENCE TO RELATED APPLICATIONS

This U.S. non-provisional patent application claims priority under 35 U.S.C. § 119 to Korean Patent Application No. 10-2023-0161506, filed on Nov. 20, 2023, in the Korean Intellectual Property Office, the entire contents of which are hereby incorporated by reference.

### BACKGROUND

### 1. Technical Field

Embodiments of the present disclosure relate to a semiconductor package, and in particular, to a semiconductor package with improved electrical and reliability characteristics and a small size.

### 2. Brief Description of Related Art

In the semiconductor industry, various package technologies have been developed in order to respond to an increase in demand for large-capacity, thin, and small semiconductor devices and/or electronic products therewith. A semiconductor package is configured to easily use an integrated-circuit chip as a part of an electronic product. In general, the semiconductor package includes a printed circuit board (PCB) and a semiconductor chip, which is mounted on the PCB and is electrically connected to the PCB using bonding wires or solder bumps. The development of the electronics industry has led to an increasing demand for high functionality, high speed, and miniaturization of semiconductor packages.

### SUMMARY

According to an embodiment of the present disclosure, a semiconductor package with improved electrical characteristics and structural stability is provided.

According to embodiments of the present disclosure, a semiconductor package is provided and includes: a lower redistribution layer; a first semiconductor chip on the lower redistribution layer; a second semiconductor chip on the first semiconductor chip; under-bump patterns between the first semiconductor chip and the second semiconductor chip; and connection terminals between the under-bump patterns and the second semiconductor chip, wherein the under-bump patterns include: a first under-bump pattern connected to two of the connection terminals; and a second under-bump pattern connected to one of the connection terminals, and wherein the first under-bump pattern is configured to receive a power or ground voltage of the second semiconductor chip.

According to embodiments of the present disclosure, a semiconductor package is provided and includes: a lower redistribution layer including lower redistribution patterns stacked in a vertical direction; a first semiconductor chip on the lower redistribution layer; a mold layer on the lower redistribution layer and covering the first semiconductor chip; an upper redistribution layer on the mold layer; and connection terminals on the upper redistribution layer, wherein the upper redistribution layer includes: a first upper insulating pattern on a top surface of the mold layer; a second upper insulating pattern in contact with the first upper insulating pattern; upper redistribution patterns between the first upper insulating pattern and the second upper insulating pattern; and under-bump patterns that penetrate the second upper insulating pattern and connect to the upper redistribution patterns, and wherein at least one of the under-bump patterns is connected to at least two of the connection terminals.

According to embodiments of the present disclosure, a semiconductor package is provided and includes: a lower redistribution layer including lower redistribution patterns that are vertically stacked in a vertical direction; a first semiconductor chip on the lower redistribution layer; a connection structure on the lower redistribution layer and horizontally spaced apart from the first semiconductor chip; an upper redistribution layer on the first semiconductor chip and the connection structure, the upper redistribution layer including under-bump patterns; a second semiconductor chip on the upper redistribution layer; and connection terminals between the upper redistribution layer and the second semiconductor chip, wherein the connection terminals are two-dimensionally arranged, when viewed in a plan view, wherein the under-bump patterns include: a first under-bump pattern connected to at least two of the connection terminals, the first under-bump pattern including pad portions and an interconnection portion between the pad portions; and a second under-bump pattern connected to one of the connection terminals, wherein the upper redistribution layer includes upper redistribution patterns, that are connected to the under-bump patterns, and an upper insulating pattern, that is on the upper redistribution patterns, and wherein the interconnection portion of the first under-bump pattern is on the upper insulating pattern.

According to an embodiment of the present disclosure, a semiconductor package with a reduced size is provided.

### BRIEF DESCRIPTION OF DRAWINGS

FIG. 1 is a plan view illustrating a semiconductor package according to an embodiment of the present disclosure.

FIG. 2 is a sectional view, which is taken along a line A-A′ of FIG. 1 to illustrate a semiconductor package according to an embodiment of the present disclosure.

FIG. 3 is a diagram illustrating a portion P1 of FIG. 1.

FIG. 4 is a diagram illustrating a portion P2 of FIG. 2.

FIG. 5 is a plan view illustrating a semiconductor package according to an embodiment of the present disclosure.

FIG. 6 is a sectional view, which is taken along a line B-B′ of FIG. 5 to illustrate a semiconductor package according to an embodiment of the present disclosure.

FIG. 7 is a diagram illustrating a portion P3 of FIG. 5.

FIG. 8 is a diagram illustrating a portion P4 of FIG. 5.

FIG. 9 is a plan view illustrating a semiconductor package according to an embodiment of the present disclosure.

FIG. 10 is a sectional view, which is taken along a line C-C′ of FIG. 9 to illustrate a semiconductor package according to an embodiment of the present disclosure.

### DETAILED DESCRIPTION

Non-limiting example embodiments of the present disclosure will now be described more fully with reference to the accompanying drawings, in which example embodiments are shown. Like reference numerals in the drawings denote like elements, and thus repeated description thereof may be omitted.

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

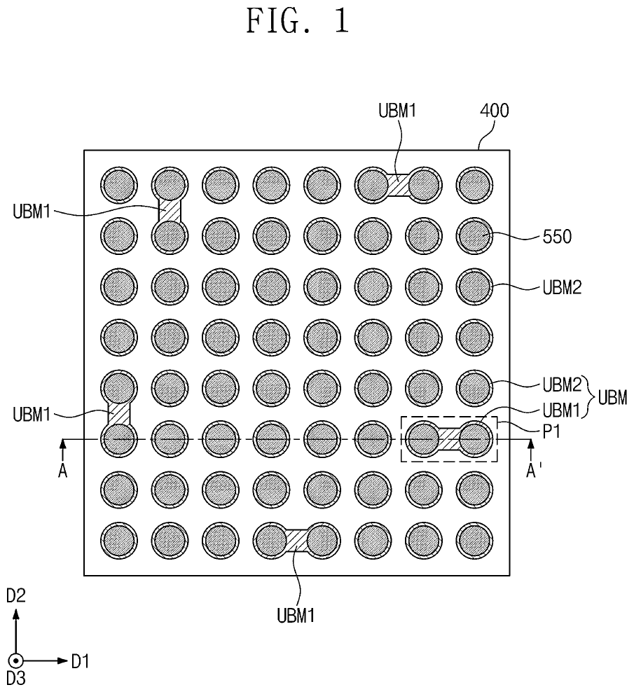

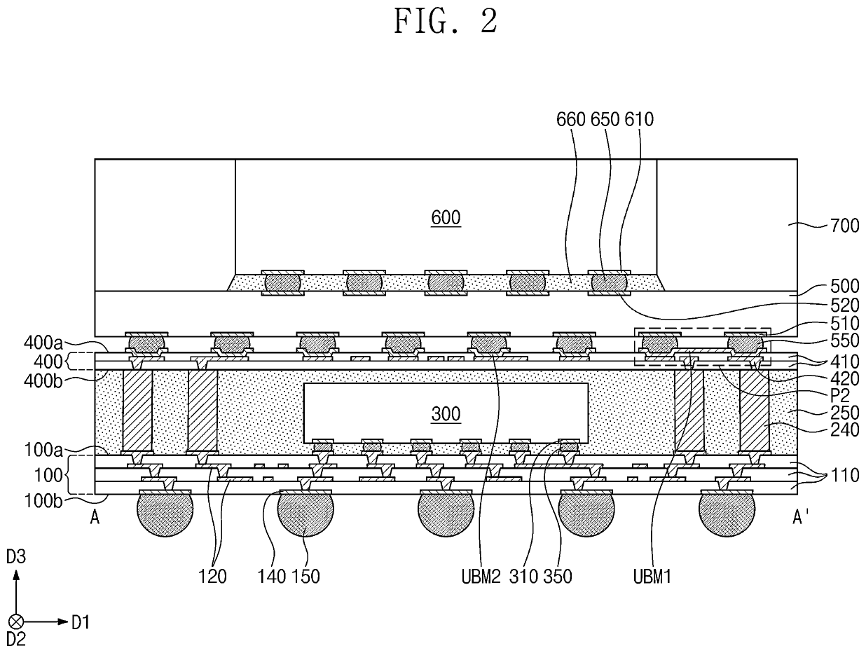

FIG. 1 is a plan view illustrating a semiconductor package according to an embodiment of the present disclosure. FIG. 2 is a sectional view, which is taken along a line A-A′ of FIG. 1 to illustrate a semiconductor package according to an embodiment of the present disclosure.

Referring to FIGS. 1 and 2, a semiconductor package may include a lower package including a first semiconductor chip 300 and an upper package including a second semiconductor chip 600. The upper package may be placed on the lower package, and the lower package and the upper package may be electrically connected to each other. For example, the semiconductor package may have a package-on-package (POP) structure.

A lower redistribution layer 100 may be provided in a lower portion of the semiconductor package. The lower redistribution layer 100 may include lower insulating patterns 110, lower redistribution patterns 120, and outer terminal pads 140. The lower redistribution layer 100 may have a bottom surface 100b and a top surface 100a, which are opposite to each other. The top surface 100a of the lower redistribution layer 100 may be located at a level (or height) higher than the bottom surface 100b of the lower redistribution layer 100.

The lower insulating patterns 110 may be stacked in a vertical direction (e.g., a third direction D3). The lower insulating patterns 110 may have substantially the same thickness as each other, but embodiments of the present disclosure are not limited to this example. A top surface of the uppermost one of the lower insulating patterns 110 may be the top surface 100a of the lower redistribution layer 100. A bottom surface of the lowermost one of the lower insulating patterns 110 may be the bottom surface 100b of the lower redistribution layer 100.

The lower insulating patterns 110 may be formed of or include, for example, polymer. For example, the lower insulating patterns 110 may be formed of or include an insulating polymer or a photoimageable dielectric (PID) material. For example, the PID materials may be formed of or include at least one from among photoimageable polyimide, polybenzoxazole (PBO), phenol-based polymers, or benzocyclobutene-based polymers. Alternatively, the lower insulating patterns 110 may include an insulating material. For example, the lower insulating patterns 110 may be formed of or include at least one from among silicon oxide (SiO), silicon nitride (SiN), silicon oxynitride (SiON), and insulating polymers.

The lower redistribution patterns 120 may be placed between the lower insulating patterns 110. The lower redistribution patterns 120 may be used to electrically connect elements, which are provided on the top surface 100a and the bottom surface 100b of the lower redistribution layer 100, to each other. In other words, the lower redistribution patterns 120 may be elements for horizontal redistribution in the lower redistribution layer 100. The lower redistribution patterns 120 may include a conductive material. For example, the lower redistribution patterns 120 may be formed of or include at least one from among metallic materials (e.g., copper (Cu)).

The lower redistribution patterns 120 may have a damascene structure. In detail, each of the lower redistribution patterns 120 may include an interconnection portion, which is placed on the top surface of the lower insulating pattern 110, and a via portion, which is extended from the interconnection portion toward the bottom surface 100b of the lower redistribution layer 100. That is, each of the lower redistribution patterns 120 may have a shape of the letter “T.”

Since the lower redistribution patterns 120 are placed between the plurality of the lower insulating patterns 110, the lower redistribution patterns 120 may be spaced apart from each other in a vertical direction or in a horizontal direction (e.g., a first direction D1 or a second direction D2). At least two of the lower redistribution patterns 120 may have top surfaces that are located at different levels from each other. That is, the lower redistribution patterns 120 of the lower redistribution layer 100 may be provided to form a plurality of layers.

The interconnection portions of the lower redistribution patterns 120 may be extended in a horizontal direction, on the top surfaces of the lower insulating patterns 110. The via portions of the lower redistribution patterns 120 may be provided to partially penetrate the lower insulating patterns 110. The via portions of the lower redistribution patterns 120 may be used to connect the interconnection portions of the lower redistribution patterns 120, which are adjacent to each other in the third direction D3, to each other. In an embodiment, the via portion of the lower redistribution pattern 120 may have a width that decreases as a distance from the top surface 100a of the lower redistribution layer 100 increases in a direction toward the bottom surface 100b of the lower redistribution layer 100.

The outer terminal pads 140 may be placed in the lowermost one of the lower insulating patterns 110. The outer terminal pads 140 may be connected to the via portions of the lowermost ones of the lower redistribution patterns 120. The outer terminal pads 140 may be connected to outer terminals 150, which will be described below. In an embodiment, some of the lower redistribution patterns 120 may be used as the outer terminal pads 140.

The outer terminals 150 may be provided on bottom surfaces of the outer terminal pads 140, respectively. The outer terminals 150 may be in contact with and electrically connected to the bottom surfaces of the outer terminal pads 140, respectively. The outer terminals 150 may be formed of or include an alloy including at least one from among tin (Sn), silver (Ag), copper (Cu), nickel (Ni), bismuth (Bi), indium (In), antimony (Sb), and cerium (Ce). The semiconductor package may have a ball grid array (BGA) structure, a fine ball-grid array (FBGA) structure, or a land grid array (LGA) structure, depending on the kind or arrangement of the outer terminals 150.

The first semiconductor chip 300 may be provided on the lower redistribution layer 100. When viewed in a plan view, the first semiconductor chip 300 may be placed in a region that is overlapped with a center of the lower redistribution layer 100. The first semiconductor chip 300 may be spaced apart from the top surface 100a of the lower redistribution layer 100 in the third direction D3.

The first semiconductor chip 300 may include first chip pads 310. The first chip pads 310 may be provided at a bottom surface of the first semiconductor chip 300 and may be exposed by the bottom surface of the first semiconductor chip 300. For example, the first chip pads 310 may have bottom surfaces that are coplanar with the bottom surface of the first semiconductor chip 300.

The first semiconductor chip 300 may be a logic chip. The logic chip may include an application specific integrated circuit (ASIC) chip, an application processor (AP) chip, a central processing unit (CPU), and a graphics processing unit (GPU).

First chip terminals 350 may be provided between the first semiconductor chip 300 and the lower redistribution layer 100. In detail, the first chip terminals 350 may be respectively placed between the first chip pads 310 and the uppermost ones of the lower redistribution patterns 120. The first semiconductor chip 300 may be mounted on the lower redistribution layer 100 using the first chip terminals 350, and the first semiconductor chip 300 and the lower redistribution layer 100 may be electrically connected to each other. For example, the first chip terminals 350 may be formed of or include an alloy that contains at least one from among tin (Sn), silver (Ag), copper (Cu), nickel (Ni), bismuth (Bi), indium (In), antimony (Sb), and cerium (Ce).

Conductive pillars 240 may be provided on the lower redistribution layer 100. The conductive pillars 240 may be placed on the uppermost ones of the lower redistribution patterns 120, respectively. Each of the conductive pillars 240 may have a shape extending in the third direction D3. The conductive pillars 240 may be spaced apart from each other in a horizontal direction. The conductive pillars 240 may be provided at a side of the first semiconductor chip 300 and may be spaced apart from the first semiconductor chip 300 in a horizontal direction. When viewed in a plan view, the conductive pillars 240 may be provided on an edge region of the lower redistribution layer 100 to enclose the first semiconductor chip 300. The conductive pillars 240 may be used to electrically connect the lower redistribution layer 100 to an upper redistribution layer 400, which will be described below. In the semiconductor package, the conductive pillars 240 may be a connection structure electrically connecting the upper package to the lower package. The conductive pillars 240 may be formed of or include at least one from among metallic or conductive materials (e.g., copper (Cu)).

A first mold layer 250 may be provided on the lower redistribution layer 100. The first mold layer 250 may cover the first semiconductor chip 300. The first mold layer 250 may be placed between the first semiconductor chip 300 and the lower redistribution layer 100 to enclose the first chip terminals 350. The first mold layer 250 may be placed between the first semiconductor chip 300 and the conductive pillars 240 and between the conductive pillars 240 and may enclose the conductive pillars 240, when viewed in a plan view. A side surface of the first mold layer 250 may be aligned with (e.g., coplanar with) a side surface of the lower redistribution layer 100. The first mold layer 250 may not cover top surfaces of the conductive pillars 240. A top surface of the first mold layer 250 may be coplanar with the top surfaces of the conductive pillars 240. For example, the first mold layer 250 may include at least one from among inorganic fillers (e.g., prepreg, Ajinomoto build-up film (ABF), FR-4, and bismaleimide triazine (BT)), and/or resins containing glass fibers. The first mold layer 250 may include an epoxy molding compound (EMC).

In the semiconductor package according to an embodiment of the present disclosure, the first semiconductor chip 300 may be buried in the first mold layer 250, and thus, the first semiconductor chip 300 may be protected from outside influences. For example, the first semiconductor chip 300 may not be exposed to an external impact. Thus, the reliability and structural stability of the semiconductor package may be improved.

An upper redistribution layer 400 may be provided on the first mold layer 250. The upper redistribution layer 400 may include upper insulating patterns 410, upper redistribution patterns 420, and under-bump patterns UBM. The upper redistribution layer 400 may have a bottom surface 400b and a top surface 400a, which are opposite to each other. The top surface 400a of the upper redistribution layer 400 may be located at a level higher than a level of the bottom surface 400b of the upper redistribution layer 400. The bottom surface 400b of the upper redistribution layer 400 may be in contact with the first mold layer 250.

The upper insulating patterns 410 may be stacked in a vertical direction. The upper insulating patterns 410 may have substantially the same thickness as each other, but embodiments of the present disclosure are not limited to this example. For example, a pair of upper insulating patterns 410 may be provided. Here, a top surface of an upper one of the upper insulating patterns 410 (or a second upper insulating pattern) may be the top surface 400a of the upper redistribution layer 400. A bottom surface of a lower one of the upper insulating patterns 410 (or a first upper insulating pattern) may be the bottom surface 400b of the upper redistribution layer 400. The upper insulating patterns 410 may include substantially the same material as a material of the lower insulating patterns 110, but embodiments of the present disclosure are not limited to this example.

The upper redistribution patterns 420 may be placed between the upper insulating patterns 410. The upper redistribution patterns 420 may be configured to electrically connect elements, which are provided on the top surface 400a and the bottom surface 400b of the upper redistribution layer 400, to each other. The upper redistribution patterns 420 may be elements for horizontal redistribution in the upper redistribution layer 400, similar to the lower redistribution patterns 120.

Since the upper redistribution patterns 420 are provided between the pair of the upper insulating patterns 410, the upper redistribution patterns 420 may be spaced apart from each other in a horizontal direction, but not in a vertical direction. Top surfaces of the upper redistribution patterns 420 may be located at the same level as each other. In other words, the upper redistribution patterns 420 of the upper redistribution layer 400 may be provided to form a single layer. Thus, a thickness of the upper redistribution layer 400 in the vertical direction may be smaller than a thickness of the lower redistribution layer 100 in the vertical direction.

Since, similar to the lower redistribution patterns 120, the upper redistribution patterns 420 have a damascene structure, each of the upper redistribution patterns 420 may include an interconnection portion and a via portion, which is vertically extended from the interconnection portion. The interconnection portions of the upper redistribution patterns 420 may be placed on a top surface of the lower one of the upper insulating patterns 410 (or the first upper insulating pattern). The interconnection portions of the upper redistribution patterns 420 may be extended in a horizontal direction. The via portions of the upper redistribution patterns 420 may be protruding portions which are extended from the interconnection portions to penetrate the lower one of the upper insulating patterns 410 (or the first upper insulating pattern).

The via portions of some of the upper redistribution patterns 420 may be connected to the conductive pillars 240. The via portions of the upper redistribution patterns 420 may be used to connect the interconnection portions of the upper redistribution patterns 420 to the conductive pillars 240. Thus, the conductive pillars 240 may be electrically connected to the under-bump patterns UBM through the upper redistribution patterns 420. The via portions of the upper redistribution patterns 420 may have a width that decreases as a distance from the top surface 400a of the upper redistribution layer 400 increases in a direction toward the bottom surface 400b.

The under-bump patterns UBM and connection terminals 550 may be provided on the upper redistribution patterns 420. The under-bump patterns UBM may be placed on the upper redistribution patterns 420, respectively. The connection terminals 550 may be placed on the under-bump patterns UBM, respectively. The under-bump patterns UBM may be formed of or include at least one from among metallic or conductive materials (e.g., copper (Cu)). The connection terminals 550 may be formed of or include an alloy containing at least one from among tin (Sn), silver (Ag), copper (Cu), nickel (Ni), bismuth (Bi), indium (In), antimony (Sb), and cerium (Ce).

The under-bump patterns UBM may include first under-bump patterns UBM1 and second under-bump patterns UBM2. Each of the first under-bump patterns UBM1 may be connected to corresponding two of the connection terminals 550. Each of the second under-bump patterns UBM2 may be connected to a corresponding one of the connection terminals 550. For example, the connection terminals 550, which are connected to the first under-bump patterns UBM1, may be adjacent to each other in a horizontal direction.

The under-bump patterns UBM and the connection terminals 550 may be two-dimensionally arranged. For example, the under-bump patterns UBM may be spaced apart from each other in the first direction D1 and the second direction D2, and the connection terminals 550 may also be spaced apart from each other in the first direction D1 and the second direction D2. When viewed in a plan view, the under-bump patterns UBM may be overlapped with corresponding ones of the connection terminals 550. For example, each of the first under-bump patterns UBM1 may be overlapped with corresponding two of the connection terminals 550, and each of the second under-bump patterns UBM2 may be overlapped with a corresponding one of the connection terminals 550.

An upper package substrate 500 may be provided on the connection terminals 550, the second semiconductor chip 600 may be mounted on the upper package substrate 500, and a second mold layer 700 may be provided to cover the second semiconductor chip 600.

The upper package substrate 500 may include lower pads 510, upper pads 520, and interconnection patterns. For example, the upper pads 520 may be at a top surface of the upper package substrate 500 and may be exposed by the top surface of the upper package substrate 500. The lower pads 510 may be at a bottom surface of the upper package substrate 500 and may be exposed by the bottom surface of the upper package substrate 500. In other words, top surfaces of the upper pads 520 may be coplanar with the top surface of the upper package substrate 500, and bottom surfaces of the lower pads 510 may be coplanar with the bottom surface of the upper package substrate 500. The upper pads 520 and the lower pads 510 may be spaced apart from each other in a vertical direction. The interconnection patterns may be provided in the upper package substrate 500 to electrically connect the upper pads 520 to the lower pads 510. In an embodiment, the upper pads 520, the lower pads 510, and the interconnection patterns may be formed of or include at least one from among metallic or conductive materials (e.g., copper (Cu)).

The second semiconductor chip 600 may be located on the upper package substrate 500. The second semiconductor chip 600 may include second chip pads 610. The second chip pads 610 may be placed in a lower portion of the second semiconductor chip 600 and may be exposed by a bottom surface of the second semiconductor chip 600. The second chip pads 610 may be spaced apart from each other in a horizontal direction. The second semiconductor chip 600 may be a different kind of semiconductor chip from the first semiconductor chip 300. For example, the second semiconductor chip 600 may be a memory chip. The memory chip may be a dynamic random access memory (DRAM) chip.

Second chip terminals 650 may be provided between the second semiconductor chip 600 and the upper package substrate 500. The second chip terminals 650 may be placed between the second chip pads 610 of the second semiconductor chip 600 and the upper pads 520 of the upper package substrate 500 and may electrically connect the second semiconductor chip 600 to the upper package substrate 500. The second chip terminals 650 may include substantially the same material as a material of the first chip terminals 350, but embodiments of the present disclosure are not limited to this example.

An under-fill layer 660 may be provided between the second semiconductor chip 600 and the upper package substrate 500 to enclose the second chip terminals 650. The under-fill layer 660 may cover side surfaces of the second chip terminals 650. The under-fill layer 660 may have an inclined side surface, but embodiments of the present disclosure are not limited to this example. Owing to the presence of the under-fill layer 660, the second chip terminals 650 may not be exposed to the outside, and this may make it possible to improve the durability of the second chip terminals 650.

In an embodiment, the second chip terminals 650 and the under-fill layer 660 may be omitted. In this case, the second semiconductor chip 600 may be mounted on the upper package substrate 500 in a direct bonding manner. In other words, the bottom surface of the second semiconductor chip 600 may be in contact with the top surface of the upper package substrate 500. The second chip pads 610 of the second semiconductor chip 600 and the upper pads 520 of the upper package substrate 500 may be in contact with each other and may form a hybrid bonding structure. In the present specification, the hybrid bonding structure may mean a bonding structure that is formed by two materials, which are of the same kind and are fused at an interface therebetween. The second chip pads 610 and the upper pads 520, which are in contact with each other, may be bonded to each other to form a single object, and in this case, there may be no observable or visible interface therebetween. Since the second chip terminals 650 are omitted from the region between the second semiconductor chip 600 and the upper package substrate 500, the size of the semiconductor package may be reduced.

The second mold layer 700 may be provided on the upper package substrate 500 to enclose the second semiconductor chip 600. The second mold layer 700 may cover a side surface of the second semiconductor chip 600 and a side surface of the under-fill layer 660. A side surface of the second mold layer 700 may be aligned with (e.g., coplanar with) a side surface of the upper package substrate 500. A top surface of the second mold layer 700 may be coplanar with a top surface of the second semiconductor chip 600, but embodiments of the present disclosure are not limited to this example. That is, the second mold layer 700 may cover the top surface of the second semiconductor chip 600. According to embodiments, the second mold layer 700 may be formed of or include substantially the same material as a material of the first mold layer 250, but embodiments of the present disclosure are not limited to this example.

In an embodiment, power and ground voltages of the second semiconductor chip 600 may be applied to the first under-bump patterns UBM1, and each of the first under-bump patterns UBM1 may be connected to two connection terminals 550. Thus, in the case where the power or ground voltage of the second semiconductor chip 600 are applied to one of the first under-bump patterns UBM1, the power and/or ground voltages may be delivered through two connection terminals 550. An input/output signal of the second semiconductor chip 600 may be transmitted to the second under-bump pattern UBM2. In other words, even when the upper redistribution patterns 420 form a single layer, the power transfer efficiency and the signal transfer efficiency in the second semiconductor chip 600 may not be reduced, because the first under-bump pattern UBM1 is used as a routing line delivering the power or ground voltage. Furthermore, the upper redistribution layer 400 of the semiconductor package may have a reduced vertical thickness. In the case where the thickness of the first semiconductor chip 300 or the second semiconductor chip 600 is increased due to the reduced vertical thickness of the upper redistribution layer 400, it may be possible to improve the heat-dissipation performance of the semiconductor package. As a result, it may be possible to reduce the size of the semiconductor package or improve the electrical characteristics and structural stability of the semiconductor package.

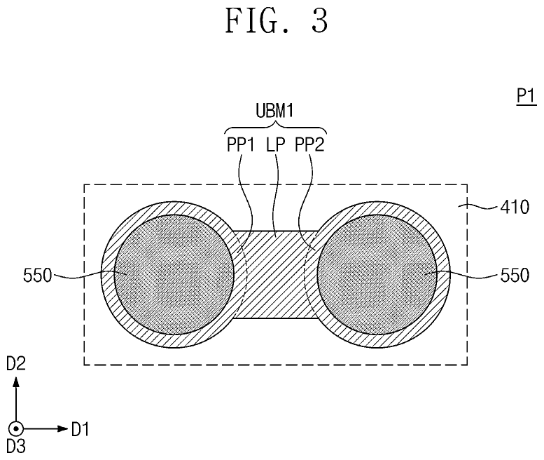

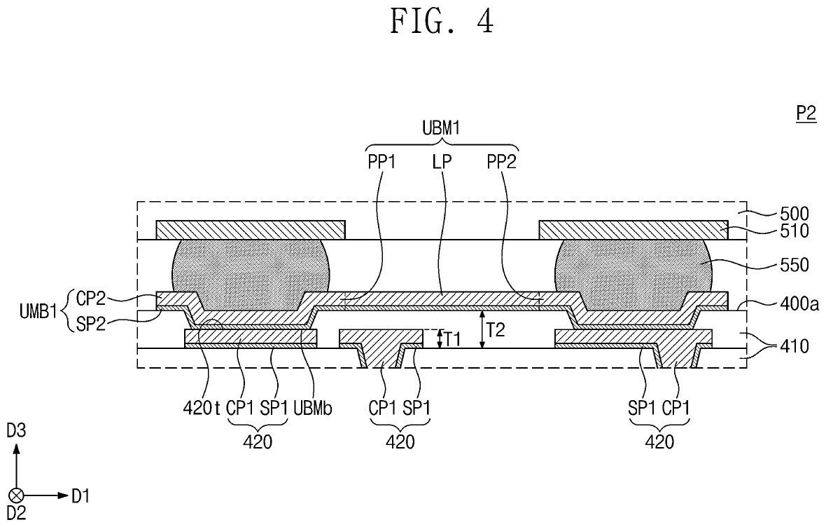

FIG. 3 is a diagram illustrating a portion P1 of FIG. 1. FIG. 4 is a diagram illustrating a portion P2 of FIG. 2.

Referring to FIGS. 3 and 4, the upper redistribution patterns 420 may be provided between the upper insulating patterns 410 and may be spaced apart from each other in a horizontal direction. Since the upper redistribution patterns 420 are not spaced apart from each other in a vertical direction, top surfaces 420t of the upper redistribution patterns 420 may be located at the same level as each other. For example, the upper redistribution patterns 420 may be placed between a lower one of the upper insulating patterns 410 (or a first upper insulating pattern) and an upper one of the upper insulating patterns 410 (or a second upper insulating pattern), and the upper insulating patterns 410 may be in contact with each other.

Each of the upper redistribution patterns 420 may include a first seed/barrier pattern SP1 and a first conductive pattern CP1. The first conductive pattern CP1 may be located on the first seed/barrier pattern SP1. For example, the first seed/barrier pattern SP1 may be in contact with a top surface of the lower one of the upper insulating patterns 410 (or the first upper insulating pattern). The first conductive pattern CP1 may be spaced apart from the lower one of the upper insulating patterns 410 (or the first upper insulating pattern) in the third direction D3 and may be placed in the upper one of the upper insulating patterns 410 (or the second upper insulating pattern). The first seed/barrier pattern SP1 and the first conductive pattern CP1 may have side surfaces that are aligned with (e.g., coplanar with) each other. The first seed/barrier pattern SP1 may prevent a material in the first conductive pattern CP1 from being diffused into other elements. The first seed/barrier pattern SP1 may include a material that is different from the material of the first conductive pattern CP1. For example, the first seed/barrier pattern SP1 may include at least one from among copper (Cu), titanium (Ti), and titanium nitride (TiN), and the first conductive pattern CP1 may include copper (Cu).

According to embodiments, each of the lower redistribution patterns 120 of FIG. 2 may include a seed/barrier pattern and a conductive pattern on the seed/barrier pattern. For example, the lower redistribution patterns 120 of FIG. 2 may have substantially the same structure as the upper redistribution patterns 420, but embodiments of the present disclosure are not limited to this example.

The interconnection portions of the upper redistribution patterns 420 may have a first thickness T1 in the third direction D3. The upper insulating patterns 410 covering the upper redistribution patterns 420 may have a second thickness T2 in the third direction D3. The first thickness T1 may be about ½ of the second thickness T2. In an embodiment, the first thickness T1 may be about 5 μm, and the second thickness T2 may be about 10 μm.

The first under-bump pattern UBM1 may be provided on the upper redistribution patterns 420. The connection terminals 550 may be provided between the first under-bump pattern UBM1 and the lower pads 510 of the upper package substrate 500. In other words, the first under-bump pattern UBM1 and the connection terminals 550 may be placed between the upper redistribution patterns 420 and the upper package substrate 500.

The first under-bump pattern UBM1 may include a second seed/barrier pattern SP2 and a second conductive pattern CP2 on the second seed/barrier pattern SP2. The second seed/barrier pattern SP2 and the second conductive pattern CP2 may have side surfaces that are aligned with (e.g., coplanar with) each other. The second seed/barrier pattern SP2 and the second conductive pattern CP2 may include substantially the same materials as the materials of the first seed/barrier pattern SP1 and the first conductive pattern CP1, respectively, and may have the same functions as the functions of the first seed/barrier pattern SP1 and the first conductive pattern CP1, respectively.

In addition, the first under-bump pattern UBM1 may include a first pad portion PP1, a second pad portion PP2, and an interconnection portion LP. The first pad portion PP1 and the second pad portion PP2 may be spaced apart from each other in the first direction D1. When viewed in a plan view, each of the first pad portion PP1 and the second pad portion PP2 may be overlapped with a corresponding one of the connection terminals 550. A planar area of each of the first pad portion PP1 and the second pad portion PP2 may be larger than a planar area of each of the connection terminals 550. Thus, each of the connection terminals 550 may overlap with a corresponding one of the first pad portion PP1 and the second pad portion PP2, and each of the connection terminals 550 may not be spaced apart from the corresponding one of the first pad portion PP1 and the second pad portion PP2 in a horizontal direction. When viewed in a plan view, each of the first pad portion PP1 and the second pad portion PP2 may have a circular shape, but embodiments of the present disclosure are not limited to this example. For example, the first pad portion PP1 and the second pad portion PP2 may have various shapes (e.g., tetragonal, rectangular, square, and elliptical shapes), when viewed in a plan view. When viewed in a vertical section, each of the first pad portion PP1 and the second pad portion PP2 may be provided to at least partially penetrate the upper one of the upper insulating patterns 410 (or the second upper insulating pattern) and may have a bottom surface UBMb in contact with the top surfaces 420t of the upper redistribution patterns 420. Center and edge portions of each of the first pad portion PP1 and the second pad portion PP2 may be located at different levels from each other.

The interconnection portion LP of the first under-bump pattern UBM1 may be positioned between the first pad portion PP1 and the second pad portion PP2. The interconnection portion LP, the first pad portion PP1, and the second pad portion PP2 may be provided in the form of a single object. The interconnection portion LP, the first pad portion PP1, and the second pad portion PP2 may be elements that are formed at the same time during the fabrication process. When viewed in a plan view, the interconnection portion LP may be spaced apart from the connection terminals 550 in the first direction D1. The interconnection portion LP may be spaced apart from the connection terminals 550 in a horizontal direction and may not be overlapped with the connection terminals 550. A width of the interconnection portion LP in the second direction D2 may be smaller than a diameter of each of the first pad portion PP1 and the second pad portion PP2.

When viewed in a vertical section, the interconnection portion LP may be placed on the upper insulating patterns 410. The interconnection portion LP may be in contact with a top surface of the upper one of the upper insulating patterns 410 (or the second upper insulating pattern). The interconnection portion LP may electrically connect the first pad portion PP1 to the second pad portion PP2. Thus, even when a power or ground voltage is applied to one of the upper redistribution patterns 420 connected to the first pad portion PP1 and the second pad portion PP2, it may be delivered to the second semiconductor chip 600 of FIG. 2 through two connection terminals 550, which are connected to the first under-bump pattern UBM1.

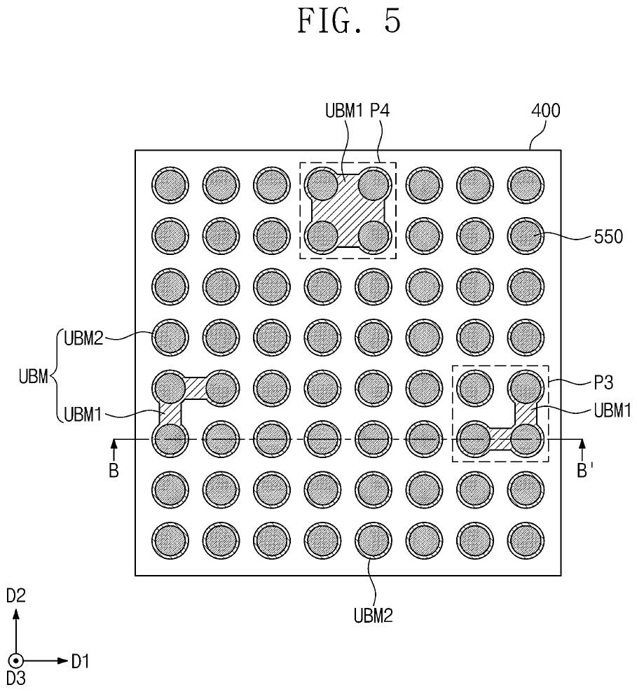

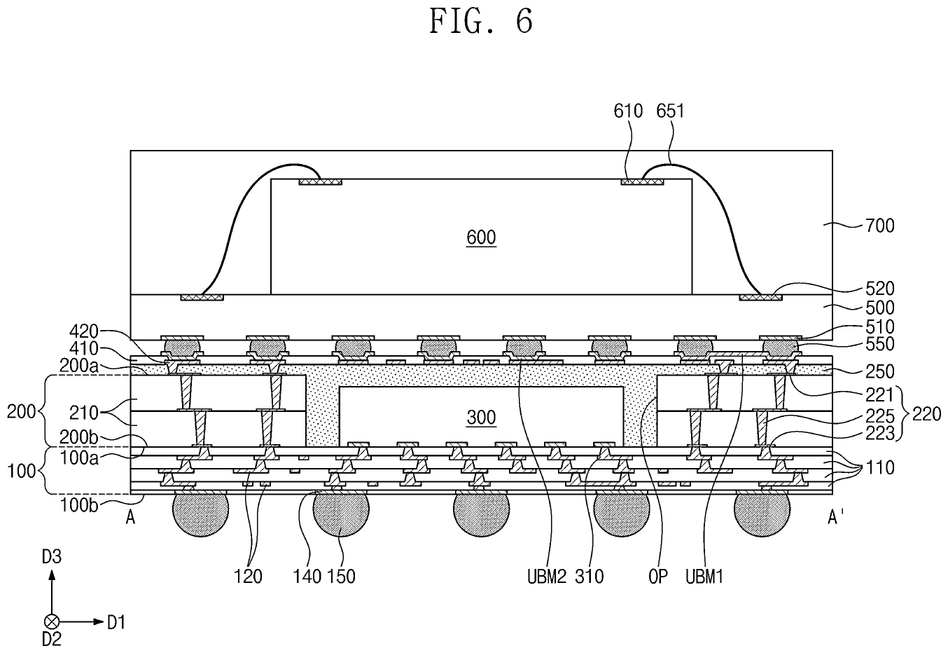

FIG. 5 is a plan view illustrating a semiconductor package according to an embodiment of the present disclosure. FIG. 6 is a sectional view, which is taken along a line B-B′ of FIG. 5 to illustrate a semiconductor package according to an embodiment of the present disclosure.

Referring to FIGS. 5 and 6, the semiconductor package may include a lower package including the first semiconductor chip 300 and an upper package including the second semiconductor chip 600. The upper package may be placed on the lower package, and the lower package and the upper package may be electrically connected to each other. For example, the semiconductor package may have a package-on-package (POP) structure.

The lower redistribution layer 100 may be provided in a lower portion of the semiconductor package. The lower redistribution layer 100 may include the lower insulating patterns 110, the lower redistribution patterns 120, and the outer terminal pads 140. The lower insulating patterns 110 and the outer terminal pads 140 may have substantially the same features as those in the embodiment described with reference to FIG. 2.

The lower redistribution patterns 120 may be placed between the lower insulating patterns 110. The lower redistribution patterns 120 may include interconnection portions, which are located on bottom surfaces of the lower insulating patterns 110, and via portions, which are extended from the interconnection portions in the third direction D3. Here, the lower redistribution patterns 120 may have an inverted shape of the letter “T.” The via portions of the lower redistribution patterns 120 may have a width that decreases as a distance from the bottom surface 100b of the lower redistribution layer 100 increases in a direction toward the top surface 100a.

A connection substrate 200 may be provided on the lower redistribution layer 100. The connection substrate 200 may have an opening OP which is formed to penetrate the same. For example, the opening OP may have an open hole that extends from a top surface 200a to a bottom surface 200b of the connection substrate 200. The bottom surface 200b of the connection substrate 200 may be in contact with the top surface 100a of the lower redistribution layer 100. The opening OP may be defined as a space, in which the first semiconductor chip 300 is placed. That is, the first semiconductor chip 300 may be provided in the form of a fan-out panel level package (FO-PLP).

The connection substrate 200 may include base layers 210 and a conductive portion 220, which is placed in the base layers 210. The base layers 210 may be stacked in a vertical direction. For example, a top surface of the uppermost one of the base layers 210 may be the top surface 200a of the connection substrate 200, and a bottom surface of the lowermost one of the base layers 210 may be the bottom surface 200b of the connection substrate 200.

The conductive portion 220 may be disposed between the opening OP and an outer side surface of the connection substrate 200. The conductive portion 220 may include upper pads 221, lower pads 223, and connection vias 225. The upper pads 221 may be disposed on a top surface of the uppermost one of the base layers 210, but embodiments of the present disclosure are not limited to this example. For example, the upper pads 221 may be buried in the uppermost one of the base layers 210, and top surfaces of the upper pads 221 may be coplanar with the top surface 200a of the connection substrate 200. The lower pads 223 may be disposed on a bottom surface of the lowermost one of the base layers 210. The lower pads 223 may be buried in the lowermost one of the base layers 210, and bottom surfaces of the lower pads 223 may be coplanar with the bottom surface 200b of the connection substrate 200.

The connection vias 225 may be provided to penetrate the base layers 210 and electrically connect the upper pads 221 to the lower pads 223. Each of the connection vias 225 may have top and bottom widths, which are measured at its top and bottom levels in a horizontal direction and are different from each other. For example, the width of the connection via 225 may increase as a distance from the bottom surface 200b of the connection substrate 200 increases in a direction toward the top surface 200a of the connection substrate 200. That is, the width of each of the connection vias 225 may increase as a height in the third direction D3 increases.

In an embodiment, the base layers 210 may be formed of or include at least one from among insulating polymers, photoimageable dielectric (PID) materials, and insulating materials. The upper pads 221, the lower pads 223, and the connection vias 225 may be formed of or include at least one from among metallic or conductive materials (e.g., copper (Cu)).

The connection substrate 200 may be mounted on the lower redistribution layer 100. That is, the connection substrate 200 may be in contact with and electrically connected to the lower redistribution layer 100. The via portions of the uppermost ones of the lower redistribution patterns 120 may penetrate the uppermost one of the lower insulating patterns 110 and may be connected to the lower pads 223 of the connection substrate 200. In addition, the connection substrate 200 may be electrically connected to the upper redistribution patterns 420. In the semiconductor package according to the present embodiment, the connection substrate 200 may be a connection structure electrically connecting the upper package to the lower package.

The first semiconductor chip 300 may be placed in the opening OP of the connection substrate 200 and may be mounted on the top surface 100a of the lower redistribution layer 100 in a direct bonding manner. In an embodiment, the bottom surface of the first semiconductor chip 300 may be in contact with the top surface 100a of the lower redistribution layer 100. The first chip pads 310 may be connected to the uppermost ones of the lower redistribution patterns 120. Thus, the first semiconductor chip 300 may be electrically connected to the lower redistribution layer 100. The first semiconductor chip 300 may be electrically connected to the outer terminals 150 through the lower redistribution layer 100. Since the solder ball or the solder bump is omitted between the first semiconductor chip 300 and the lower redistribution layer 100, the size of the semiconductor package may be reduced.

The first mold layer 250 may be provided to cover the connection substrate 200 and the first semiconductor chip 300. The first mold layer 250 may be provided to fill a remaining portion of the opening OP of the connection substrate 200. The first mold layer 250 may be extended into a gap between the connection substrate 200 and the first semiconductor chip 300 and may be in contact with a portion of the lower redistribution layer 100. That is, a portion of the first mold layer 250 may be located between the connection substrate 200 and the first semiconductor chip 300.

The upper redistribution patterns 420 and the upper insulating pattern 410 may be provided on the first mold layer 250. The upper insulating pattern 410 may cover the upper redistribution patterns 420 and the top surface of the first mold layer 250. The upper redistribution patterns 420 may include interconnection portions, which are located on the first mold layer 250, and via portions, which are provided to partially penetrate the first mold layer 250. The interconnection portions of the upper redistribution patterns 420 may have a shape extending in a horizontal direction, on the first mold layer 250. The via portions of the upper redistribution patterns 420 may be connected to the upper pads 221 of the connection substrate 200. Since the upper redistribution patterns 420 are spaced apart from each other in a horizontal direction, the upper redistribution patterns 420 may be located at substantially the same level as each other.

The under-bump patterns UBM may be provided on the upper redistribution patterns 420, and the connection terminals 550 may be provided on the under-bump patterns UBM. The connection terminals 550 may have substantially the same features as those in the embodiment described with reference to FIGS. 1 and 2. The under-bump patterns UBM may include the first under-bump patterns UBM1 and the second under-bump patterns UBM2, and the second under-bump patterns UBM2 may have substantially the same features as those in the embodiment described with reference to FIGS. 1 and 2. Each of the first under-bump patterns UBM1 may be connected to three or four of the connection terminals 550. However, embodiments of the present disclosure are not limited to this example. In the semiconductor package according to an embodiment of the present disclosure, the first under-bump patterns UBM1 may be connected to at least two of the connection terminals 550. In this case, the connection terminals 550, which are connected to the first under-bump patterns UBM1, may overlap with the first under-bump patterns UBM1.

The upper package substrate 500 may be provided on the connection terminals 550, the second semiconductor chip 600 may be mounted on the upper package substrate 500, and the second mold layer 700 may be provided to cover the second semiconductor chip 600. The second semiconductor chip 600 may be in contact with the upper package substrate 500. The second semiconductor chip 600 may include the second chip pads 610, which are placed at (e.g., in or on) the top surface of the second semiconductor chip 600. The second chip pads 610 may be exposed by the top surface of the second semiconductor chip 600. In other words, top surfaces of the second chip pads 610 may be coplanar with the top surface of the second semiconductor chip 600.

Bonding wires 651 may be provided on the second semiconductor chip 600. The bonding wires 651 may connect the second chip pads 610 of the second semiconductor chip 600 to the upper pads 520 of the upper package substrate 500. Accordingly, the second semiconductor chip 600 and the upper package substrate 500 may be electrically connected to each other.

The second mold layer 700 may be provided on the upper package substrate 500 to cover the second semiconductor chip 600 and the bonding wires 651. The second mold layer 700 may have a top surface, which is located at a level higher than a level of the top surface of the second semiconductor chip 600, and in this case, it may be possible to protect the bonding wires 651 from the outside.

In the semiconductor package according to an embodiment of the present disclosure, the first under-bump patterns UBM1 may be connected to at least two terminals of the connection terminals 550. This may mean that a power voltage and a ground voltage can be applied to the second semiconductor chip 600 through the plurality of connection terminals 550. Accordingly, it may be possible to improve the power transfer efficiency and the signal transfer efficiency in the second semiconductor chip 600.

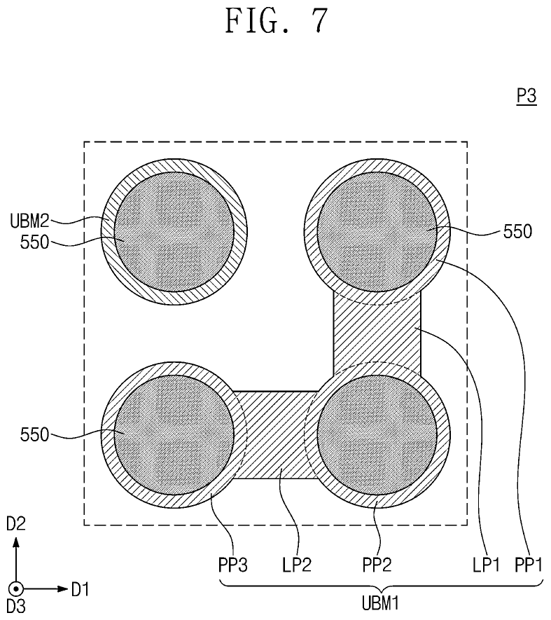

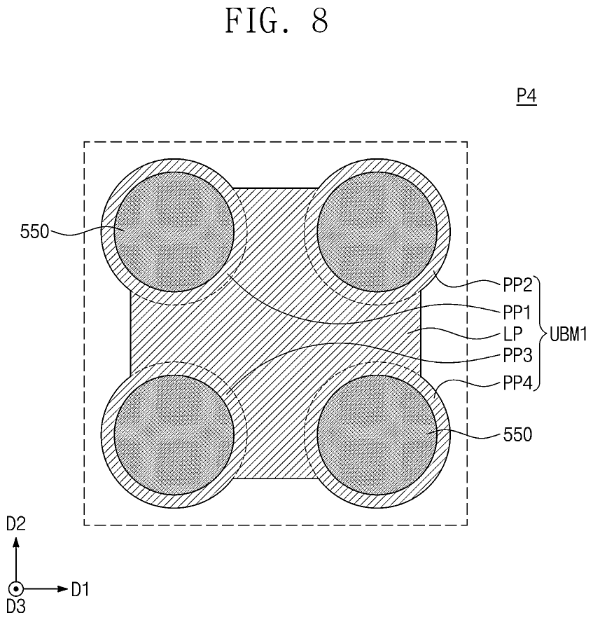

FIG. 7 is a diagram illustrating a portion P3 of FIG. 5. FIG. 8 is a diagram illustrating a portion P4 of FIG. 5.

Referring to FIG. 7, the first under-bump pattern UBM1 may include the first pad portion PP1, the second pad portion PP2, a third pad portion PP3, a first interconnection portion LP1, and a second interconnection portion LP2. For example, the first pad portion PP1, the second pad portion PP2, the third pad portion PP3, the first interconnection portion LP1, and the second interconnection portion LP2 may be formed in the form of a single object. For example, the first pad portion PP1, the second pad portion PP2, the third pad portion PP3, the first interconnection portion LP1, and the second interconnection portion LP2 may be formed at the same time.

The first pad portion PP1, the second pad portion PP2, and the third pad portion PP3 may be spaced apart from each other in a horizontal direction. For example, the first pad portion PP1 and the second pad portion PP2 may be spaced apart from each other in the second direction D2. The second pad portion PP2 and the third pad portion PP3 may be spaced apart from each other in the first direction D1. When viewed in a plan view, each of the first pad portion PP1, the second pad portion PP2, and the third pad portion PP3 may be overlapped with a corresponding one of the connection terminals 550.

The first interconnection portion LP1 may be placed between the first pad portion PP1 and the second pad portion PP2. The first interconnection portion LP1 may electrically connect the first pad portion PP1 to the second pad portion PP2. The second interconnection portion LP2 may be placed between the second pad portion PP2 and the third pad portion PP3. The second interconnection portion LP2 may electrically connect the second pad portion PP2 to the third pad portion PP3. In other words, the first pad portion PP1, the second pad portion PP2, and the third pad portion PP3 may be electrically connected to each other through the first interconnection portion LP1 and the second interconnection portion LP2.

Thus, in the case where a power or ground voltage is applied to one of the upper redistribution patterns 420 of FIG. 6 connected to the first pad portion PP1, the second pad portion PP2, and the third pad portion PP3, the power and ground voltages may be supplied to the second semiconductor chip 600 of FIG. 6 through three connection terminals 550.

Unlike the first under-bump pattern UBM1, the second under-bump pattern UBM2 may be composed of a single pad portion, without the interconnection portion. The second under-bump pattern UBM2 may be used to deliver an input/output signal to the second semiconductor chip 600 of FIG. 6 through one of the connection terminals 550.

Referring to FIG. 8, the first under-bump pattern UBM1 may include the first pad portion PP1, the second pad portion PP2, the third pad portion PP3, a fourth pad portion PP4, and the interconnection portion LP. In an embodiment, the first pad portion PP1, the second pad portion PP2, the third pad portion PP3, the fourth pad portion PP4, and the interconnection portion LP may be formed in the form of a single object. For example, the first pad portion PP1, the second pad portion PP2, the third pad portion PP3, the fourth pad portion PP4, and the interconnection portion LP may be elements that are formed at the same time.

The first pad portion PP1, the second pad portion PP2, the third pad portion PP3, and the fourth pad portion PP4 may be spaced apart from each other in a horizontal direction. For example, the first pad portion PP1 and the second pad portion PP2 may be spaced apart from each other in the first direction D1. The first pad portion PP1 and the third pad portion PP3 may be spaced apart from each other in the second direction D2. The second pad portion PP2 and the fourth pad portion PP4 may be spaced apart from each other in the second direction D2. The third pad portion PP3 and the fourth pad portion PP4 may be spaced apart from each other in the first direction D1. When viewed in a plan view, each of the first pad portion PP1, the second pad portion PP2, the third pad portion PP3, and the fourth pad portion PP4 may be overlapped with a corresponding one of the connection terminals 550.

The interconnection portion LP may be located between the first pad portion PP1, the second pad portion PP2, the third pad portion PP3, and the fourth pad portion PP4. The interconnection portion LP may be provided to electrically connect the first pad portion PP1, the second pad portion PP2, the third pad portion PP3, and the fourth pad portion PP4 to each other. For example, the first pad portion PP1, the second pad portion PP2, the third pad portion PP3, and the fourth pad portion PP4 may be electrically connected to each other through the interconnection portion LP.

Accordingly, in the case where a power or ground voltage is applied to one of the upper redistribution patterns 420 of FIG. 6 connected to the first pad portion PP1, the second pad portion PP2, the third pad portion PP3, and the fourth pad portion PP4, the power and ground voltages may be supplied to the second semiconductor chip 600 of FIG. 6 through four connection terminals 550.

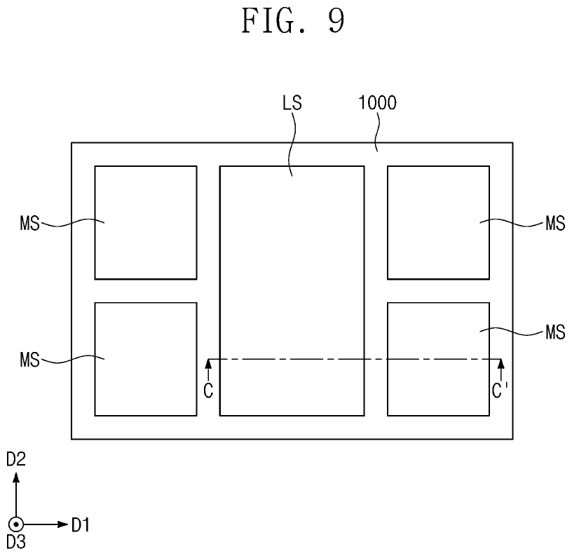

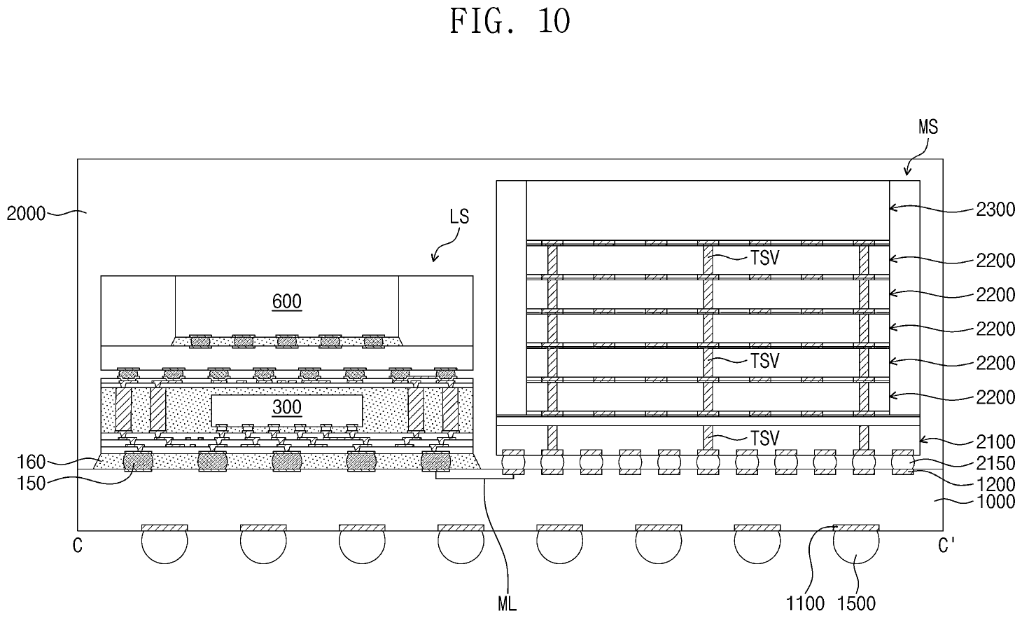

FIG. 9 is a plan view illustrating a semiconductor package according to an embodiment of the present disclosure. FIG. 10 is a sectional view, which is taken along a line C-C′ of FIG. 9 to illustrate a semiconductor package according to an embodiment of the present disclosure.

Referring to FIGS. 9 and 10, the semiconductor package may include a package substrate 1000, a logic structure LS, and a plurality of memory structures MS. When viewed in a plan view, the logic structure LS and the memory structures MS may overlap with the package substrate 1000. When viewed in a plan view, the logic structure LS may be placed in a region that overlaps with a center of the package substrate 1000, and the memory structures MS may be placed at both sides of the logic structure LS. For example, the logic structure LS may be placed between the memory structures MS, and the memory structures MS may be spaced apart from the logic structure LS.

The package substrate 1000 may include lower pads 1100, upper pads 1200, and a metal line ML. The lower pads 1100 may be placed at (e.g., in or on) a bottom surface of the package substrate 1000 and may be spaced apart from each other. The upper pads 1200 may be placed at (e.g., in or on) a top surface of the package substrate 1000 and may be spaced apart from each other. The metal line ML may electrically connect the logic structure LS and the memory structures MS, which are mounted on the package substrate 1000, to each other. For example, the package substrate 1000 may be a printed circuit board (PCB), but embodiments of the present disclosure are not limited to this example.

Package terminals 1500 may be provided on the bottom surface of the package substrate 1000. Each of the package terminals 1500 may be placed on a bottom surface of a corresponding one of the lower pads 1100. The package terminals 1500 may be coupled to the lower pads 1100 and may be electrically connected to the upper pads 1200 through the lower pads 1100. The package terminals 1500 may be formed of or include an alloy including at least one from among tin (Sn), silver (Ag), copper (Cu), nickel (Ni), bismuth (Bi), indium (In), antimony (Sb), and cerium (Ce).

The logic structure LS may be mounted on the package substrate 1000. The logic structure LS may include the first semiconductor chip 300 and the second semiconductor chip 600 on the first semiconductor chip 300. The logic structure LS may have substantially the same features as the features in the semiconductor package described with reference to FIGS. 1 and 2 or FIGS. 5 and 6.

The memory structures MS may be mounted on the package substrate 1000. Each of the memory structures MS may have a chip stack structure. Each of the memory structures MS may include a base chip 2100, a plurality of first memory chips 2200, and a second memory chip 2300, and in an embodiment, the base chip 2100, the first memory chips 2200, and the second memory chip 2300 may be stacked in a vertical direction.

The base chip 2100 may be placed in a lower portion of each of the memory structures MS. The base chip 2100 may include penetration electrodes TSV, which are formed to penetrate the same. The penetration electrodes TSV may electrically connect the base chip 2100 to the package substrate 1000 and the first memory chips 2200. In an embodiment, the base chip 2100 may include a logic chip, a controller chip, or a buffer chip. In other words, the base chip 2100 may include a different kind of semiconductor chip from the first memory chips 2200 and the second memory chip 2300.

The first memory chips 2200 may be placed on the base chip 2100. The first memory chips 2200 may be stacked in a vertical direction. Each of the first memory chips 2200 may include the penetration electrodes TSV, which are provided to penetrate the same. The penetration electrodes TSV may electrically connect adjacent ones of the first memory chips 2200 to each other. The second memory chip 2300 may be placed on the first memory chips 2200. The second memory chip 2300 may be the uppermost element of the memory structures MS. Unlike the first memory chips 2200, the second memory chip 2300 may not include the penetration electrodes TSV. In an embodiment, each of the first memory chips 2200 and the second memory chip 2300 may be a semiconductor chip including a memory cell (e.g., a dynamic random access memory (DRAM) cell, a static random access memory (SRAM) cell, a NAND FLASH memory cell, or a resistive random access memory (RRAM) cell.

The base chip 2100 may be in contact with the lowermost one of the first memory chips 2200, the first memory chips 2200 may be in contact with each other, and the uppermost one of the first memory chips 2200 may be in contact with the second memory chip 2300. However, embodiments of the present disclosure are not limited to this example, and in an embodiment, solder balls or solder bumps may be provided between the base chip 2100, the first memory chips 2200, and the second memory chip 2300.

For example, the memory structures MS may include high bandwidth memory (HBM) chips. According to embodiments, the number of the first memory chips 2200 and the second memory chip 2300, which are stacked on the base chip 2100 of each of the memory structures MS, may be variously changed. If the number of the first memory chips 2200 and/or the second memory chip 2300 is increased, the data storing capacity may be increased.

According to an embodiment of the present disclosure, a semiconductor package may include an under-bump pattern, which includes pad portions and an interconnection portion between the pad portions. The under-bump pattern may be connected to two or more connection terminals, and thus, power and ground voltages may be applied to a semiconductor chip through the two or more connection terminals. Thus, even when upper redistribution patterns are provided in the form of a single layer, it may be possible to prevent the power transfer efficiency and signal transfer efficiency of the semiconductor chip from being lowered. Accordingly, it may be possible to reduce the size of the semiconductor package.

While non-limiting example embodiments of the present disclosure have been particularly shown and described, it will be understood by one of ordinary skill in the art that variations in form and detail may be made therein without departing from the spirit and scope of the present disclosure.

What is claimed is:

1. A semiconductor package, comprising:
a lower redistribution layer;
a first semiconductor chip on the lower redistribution layer;
a second semiconductor chip on the first semiconductor chip;
under-bump patterns between the first semiconductor chip and the second semiconductor chip; and
connection terminals between the under-bump patterns and the second semiconductor chip,
wherein the under-bump patterns comprise:
a first under-bump pattern connected to two of the connection terminals; and
a second under-bump pattern connected to one of the connection terminals, and
wherein the first under-bump pattern is configured to receive a power or ground voltage of the second semiconductor chip.

2. The semiconductor package of claim 1, wherein the first under-bump pattern comprises pad portions and an interconnection portion connecting the pad portions.

3. The semiconductor package of claim 2, wherein the pad portions are respectively overlapped with the two of the connection terminals connected to the first under-bump pattern, when viewed in a plan view.

4. The semiconductor package of claim 1, further comprising a conductive pillar on the lower redistribution layer and horizontally spaced apart from the first semiconductor chip,
wherein the under-bump patterns and the lower redistribution layer are electrically connected to each other through the conductive pillar.

5. The semiconductor package of claim 1, wherein the connection terminals are two-dimensionally arranged such as to be spaced apart from each other in a first direction and a second direction that cross each other, and
the connection terminals, which are connected to the first under-bump pattern, are adjacent to each other in the first direction or the second direction.

6. The semiconductor package of claim 1, wherein the second under-bump pattern is configured to receive an input/output signal of the second semiconductor chip.

7. The semiconductor package of claim 1, wherein the first semiconductor chip comprises a logic chip, and
wherein the second semiconductor chip comprises a memory chip.

8. The semiconductor package of claim 1, further comprising:
upper redistribution patterns between the first semiconductor chip and the under-bump patterns and connected to the under-bump patterns; and
an upper insulating pattern on the upper redistribution patterns.

9. The semiconductor package of claim 8, wherein an interconnection portion of the first under-bump pattern is on the upper insulating pattern.

10. The semiconductor package of claim 8, wherein a vertical thickness of the upper insulating pattern is 10 μm.

11. A semiconductor package, comprising:
a lower redistribution layer comprising lower redistribution patterns stacked in a vertical direction;
a first semiconductor chip on the lower redistribution layer;
a mold layer on the lower redistribution layer and covering the first semiconductor chip;
an upper redistribution layer on the mold layer; and
connection terminals on the upper redistribution layer,
wherein the upper redistribution layer comprises:
a first upper insulating pattern on a top surface of the mold layer;
a second upper insulating pattern in contact with the first upper insulating pattern;
upper redistribution patterns between the first upper insulating pattern and the second upper insulating pattern; and
under-bump patterns that penetrate the second upper insulating pattern and connect to the upper redistribution patterns, and
wherein at least one of the under-bump patterns is connected to at least two of the connection terminals.

12. The semiconductor package of claim 11, wherein each of the at least one of the under-bump patterns connected to the at least two of the connection terminals comprises:
pad portions vertically overlapped with the connection terminals; and
at least one interconnection portion between the pad portions.

13. The semiconductor package of claim 11, wherein top surfaces of the upper redistribution patterns are coplanar with bottom surfaces of the under-bump patterns.

14. The semiconductor package of claim 11, wherein each of the under-bump patterns comprises a seed/barrier pattern and a conductive pattern on the seed/barrier pattern.

15. The semiconductor package of claim 11, further comprising a connection substrate that is on the lower redistribution layer and includes an opening,
wherein the first semiconductor chip is in the opening.

16. A semiconductor package, comprising:
a lower redistribution layer comprising lower redistribution patterns that are vertically stacked in a vertical direction;
a first semiconductor chip on the lower redistribution layer;
a connection structure on the lower redistribution layer and horizontally spaced apart from the first semiconductor chip;
an upper redistribution layer on the first semiconductor chip and the connection structure, the upper redistribution layer comprising under-bump patterns;
a second semiconductor chip on the upper redistribution layer; and
connection terminals between the upper redistribution layer and the second semiconductor chip,
wherein the connection terminals are two-dimensionally arranged, when viewed in a plan view,
wherein the under-bump patterns comprise:
a first under-bump pattern connected to at least two of the connection terminals, the first under-bump pattern comprising pad portions and an interconnection portion between the pad portions; and
a second under-bump pattern connected to one of the connection terminals,
wherein the upper redistribution layer comprises upper redistribution patterns, that are connected to the under-bump patterns, and an upper insulating pattern, that is on the upper redistribution patterns, and
wherein the interconnection portion of the first under-bump pattern is on the upper insulating pattern.

17. The semiconductor package of claim 16, wherein the first under-bump pattern is configured to receive a power or ground voltage of the second semiconductor chip, and
wherein the second under-bump pattern is configured to receive an input/output signal of the second semiconductor chip.

18. The semiconductor package of claim 16, wherein a thickness of the lower redistribution layer in the vertical direction is larger than a thickness of the upper redistribution layer in the vertical direction.

19. The semiconductor package of claim 16, wherein the first under-bump pattern comprises an additional interconnection portion between the pad portions.

20. The semiconductor package of claim 16, further comprising a memory structure that is horizontally spaced apart from the first semiconductor chip and the second semiconductor chip,
wherein the memory structure comprises memory chips stacked in the vertical direction.
